(19) United States
(12) Patent Application Publication
(10) Pub. No.: US 2026/0073091 A1
(43) Pub. Date: Mar. 12, 2026

(54) GENERATING ACCURATE RF MODELS

(71) Applicant: International Business Machines Corporation, Armonk, NY (US)

(72) Inventors: Ning Lu, Essex Junction, VT (US); Richard Andre Wachnik, Mount Kisco, NY (US)

(21) Appl. No.: 18/828,148

(22) Filed: Sep. 9, 2024

(51) Int. Cl. G06F 30/20

(52) U.S. Cl. CPC G06F 30/20

(57) ABSTRACT

A computer-implemented method is provided for modeling a circuit having a resistive element, an inductive element, and element pairs connected in series. The operations include determining values of the resistive element, the resistive elements, the inductive element, and the inductive elements with respect to a target DC resistance value, a target low-frequency inductance value, and a set of N target resistance values and N target inductance values at a set of N frequency values. The operations include establishing a first set of 2N equations including a first set of 2N unknowns respectively corresponding to the N target resistance values and the N target inductance values. The operations include introducing a coordinate transformation which includes replacing the first set of 2N unknowns with a second set of 2N unknowns in a transformed coordinate system.

### BACKGROUND

The present disclosure generally relates to generation of a passive device model, and more specifically, to accurate generation of a passive device model for transient SPICE simulations. The present disclosure relates to generation of accurate RF models for transient SPICE simulations including frequency-dependent transmission lines.

In the design and analysis of a power distribution network, global clock trees, coplanar waveguide analysis, and inductors, frequency-dependent resistance and inductance are first simulated or measured, and the measured resistance and inductance are then translated to a corresponding SPICE model. Some approaches may subsequently use the SPICE model for each of the power distribution network, global clock-trees, and coplanar waveguide analysis to analyze waveforms, including signal delay, signal slew, and coupling/noise between a signal wire and wires adjacent the signal wire. Techniques for building such SPICE models (which use discrete resistive and inductive elements) to accurately represent simulated/measured resistance and inductance according to frequency are desired.

### SUMMARY

Embodiments of the present disclosure are directed to computer-implemented methods for generation of accurate RF models.

Embodiments include a computer-implemented method for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value. The computer-implemented method includes determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N}). The computer-implemented method includes establishing a first set of 2N equations including a first set of 2N unknowns (r₁, r₂, . . . , r_{N} and l₁, l₂, . . . , l_{N}) respectively corresponding to the N target resistance values and the N target inductance values. The computer-implemented method includes introducing a coordinate transformation which includes replacing the first set of 2N unknowns with a second set of 2N unknowns in a transformed coordinate system, based on a first relationship. The computer-implemented method includes establishing a second relationship expressing a first subset of N unknowns in the second set of 2N unknowns in terms of a second subset of N unknowns in the second set of 2N unknowns, and establishing a second set of N equations including the second subset of N unknowns within the second set of 2N unknowns, wherein the second set of N equations are based on respectively the N target resistance values and the N target inductance values. The computer-implemented method includes determining the values of the first set of 2N unknowns (r₁, r₂, . . . , r_{N} and l₁, l₂, . . . , l_{N}) based on the first relationship and values of the second set of 2N unknowns.

Embodiments also include a computing system having a memory having computer readable instructions and one or more processors for executing the computer readable instructions. The computer readable instructions controlling the one or more processors to perform operations for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value. The operations include determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N}). The operations include establishing a first set of 2N equations including a first set of 2N unknowns (r₁, r₂, . . . , r_{N} and l₁, l₂, . . . , l_{N}) respectively corresponding to the N target resistance values and the N target inductance values. The operations include introducing a coordinate transformation which includes replacing the first set of 2N unknowns with a second set of 2N unknowns in a transformed coordinate system, based on a first relationship. The operations include establishing a second relationship expressing a first subset of N unknowns in the second set of 2N unknowns in terms of a second subset of N unknowns in the second set of 2N unknowns, and establishing a second set of N equations including the second subset of N unknowns within the second set of 2N unknowns, wherein the second set of N equations are based on respectively the N target resistance values and the N target inductance values. The operations include determining the values of the first set of 2N unknowns (r₁, r₂, . . . , r_{N} and l₁, l₂, . . . , l_{N}) based on the first relationship and values of the second set of 2N unknowns.

Embodiments also include a computer program product having a computer readable storage medium having program instructions embodied therewith. The program instructions executable by a processor to cause the processor to perform operations for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value. The operations include determining values of the resistive element rac, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N}). The operations include establishing a first set of 2N equations including a first set of 2N unknowns (r₁, r₂, . . . , r_{N} and l₁, l₂, . . . , l_{N}) respectively corresponding to the N target resistance values and the N target inductance values. The operations include introducing a coordinate transformation which includes replacing the first set of 2N unknowns with a second set of 2N unknowns in a transformed coordinate system, based on a first relationship. The operations include establishing a second relationship expressing a first subset of N unknowns in the second set of 2N unknowns in terms of a second subset of N unknowns in the second set of 2N unknowns, and establishing a second set of N equations including the second subset of N unknowns within the second set of 2N unknowns, wherein the second set of N equations are based on respectively the N target resistance values and the N target inductance values. The operations include determining the values of the first set of 2N unknowns (r₁, r₂, . . . , r_{N} and l₁, l₂, . . . , l_{N}) based on the first relationship and values of the second set of 2N unknowns.

Other embodiments of the present invention implement features of the above-described method in computer systems and computer program products.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the present disclosure are apparent from the following detailed description taken in conjunction with the accompanying drawings.

FIG. 1 illustrates a block diagram of an example computer system for use in conjunction with one or more embodiments of the present disclosure.

FIG. 2 illustrates a block diagram of an example computing system that supports generation of accurate RF models in accordance with one or more embodiments of the present disclosure.

FIG. 3 illustrates an example view of a cross section of a group of wires included in a power distribution network in accordance with one or more embodiments of the present disclosure.

FIG. 4 illustrates example plots of frequency-dependent resistance and inductance of a power distribution network in accordance with one or more embodiments of the present disclosure.

FIG. 5 illustrates example plots of frequency-dependent resistance and inductance of a power distribution network in accordance with one or more embodiments of the present disclosure.

FIG. 6 illustrates an example of a single coplanar waveguide (CPW) structure.

FIG. 7 illustrates example plots of frequency-dependent loop resistance and loop inductance of a single CPW structure in accordance with one or more embodiments of the present disclosure.

FIG. 8 is an example of results associated with modeling an example CPW structure in accordance with one or more embodiments of the present disclosure.

FIG. 9 illustrates an example flowchart of a method in accordance with one or more embodiments of the present disclosure.

FIG. 10 illustrates an example flowchart of a method in accordance with one or more embodiments of the present disclosure.

FIG. 11 illustrates an example flowchart of a method that supports the generation of accurate RF models in accordance with one or more embodiments of the present disclosure.

### DETAILED DESCRIPTION

Some VLSI chips may routinely operate in the gigahertz clocking domain, where the resistance and inductance of VLSI interconnect may exhibit frequency-dependent behavior. The EDA industry and chip companies have developed various computer automated design (CAD) tools for predicting and analyzing such frequency-dependent impedance behavior. Examples include models for global clock trees, power distribution networks, coplanar wave guides (CPWs), and the like. Recently, to further improve the performance of VLSI chips, a backside power distribution manufacturing process has been proposed. Such a new power distribution network scheme calls for an analysis of the inductance effect inherent to this scheme. Obtaining an accurate SPICE model for frequency-dependent transmission lines, and particularly, for frequency-dependent transmission lines associated with backside power distribution has again emerged as an important topic.

For example, in the design and analysis of power distribution networks, global clock trees, and transmission lines used in VLSI chips and of coplanar waveguide (CPW) devices used in radio frequency (RF) circuits, the frequency dependent resistance and inductance of the chip interconnects and in CPW devices may be represented by passive SPICE models for efficient transient analysis. In some cases, the models enable evaluation of the separation of power from clock and signal wires with backside power schemes.

According to one or more embodiments of the present disclosure, given a pair of frequency-dependent resistance and inductance target curves for a transmission line system or for a CPW device, a method for generating a passive device model for transient SPICE simulations is provided.

In some aspects, the passive device model includes (N+2) resistive and/or inductive elements. In the frequency domain, the passive device model may always reproduce (i) a given DC resistance target, (ii) a given low-frequency inductance target, and (iii) either N given high frequency resistance targets or N given high frequency inductance targets exactly. Embodiments of the present disclosure may include obtaining or generating the frequency-dependent resistance and inductance targets through a field solver simulation in the frequency domain or from on-chip hardware measurements. Descriptions herein of reproducing or matching a target (e.g., resistance target, inductance target) exactly may mean that an exact and analytic solution or an equivalent thereof is used. In spite of roundoff errors in computer calculations, 6 significant digits are easily matched exactly when a double precision is used in numerical calculations.

When the N high-frequency resistance targets are matched exactly, N high-frequency inductance targets are also well matched. When the N high-frequency inductance targets are reproduced exactly, N high-frequency resistance targets are also well reproduced. Embodiments of the present disclosure provide an exact and analytic solution for the resistive and inductive elements used in a passive circuit. The techniques described herein are capable of achieving a match between a pair of DC/low-frequency impedance target and a pair of high-frequency impedance target at one frequency point.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

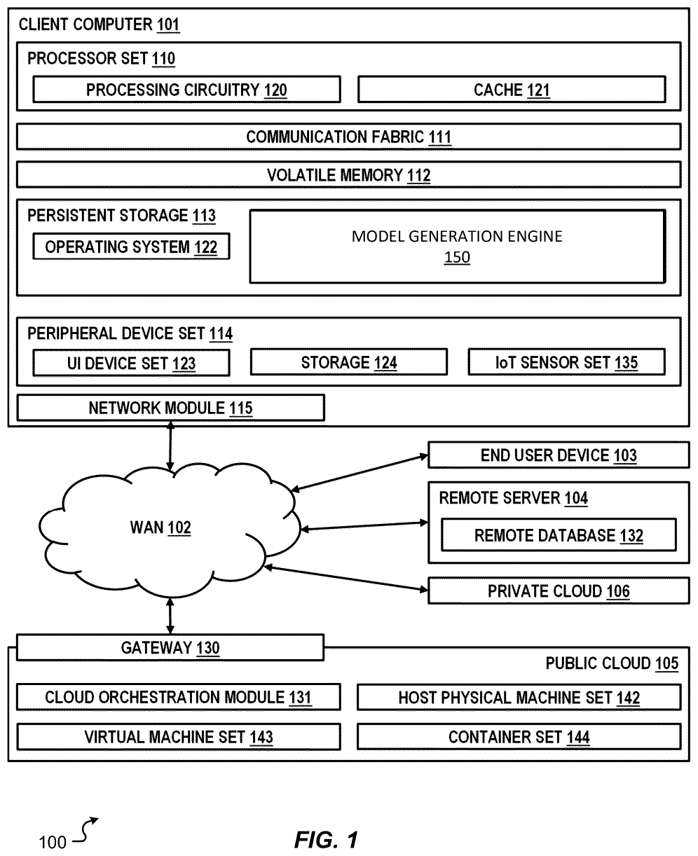

FIG. 1 illustrates a block diagram of an example computer system for use in conjunction with one or more embodiments of the present disclosure. Computing environment 100 contains an example of an environment for the execution of at least some of the computer code involved in performing the inventive methods, such as model generation by the model generation engine 150. In addition to model generation engine 150, computing environment 100 includes, for example, computer 101, wide area network (WAN) 102, end user device (EUD) 103, remote server 104, public Cloud 105, and private Cloud 106. In this embodiment, computer 101 includes processor set 110 (including processing circuitry 120 and cache 121), communication fabric 111, volatile memory 112, persistent storage 113 (including operating system 122 and model generation engine 150, as identified above), peripheral device set 114 (including user interface (UI), device set 123, storage 124, and Internet of Things (IoT) sensor set 135), and network module 115. Remote server 104 includes remote database 132. Public Cloud 105 includes gateway 130, Cloud orchestration module 131, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 132. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a Cloud, even though it is not shown in a Cloud in FIG. 1. On the other hand, computer 101 is not required to be in a Cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in model generation engine 150 in persistent storage 113.

COMMUNICATION FABRIC 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in model generation engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 135 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collects and store helpful and useful data for use by other computers, such as computer 101. For example, in a hypothetical case where computer 101 is designed and programmed to provide a recommendation based on historical data, then this historical data may be provided to computer 101 from remote database 132 of remote server 104.

PUBLIC CLOUD 105 is any computer system available for use by multiple entities that provides on-demand availability of computer system resources and/or other computer capabilities, especially data storage (Cloud storage) and computing power, without direct active management by the user. Cloud computing typically leverages sharing of resources to achieve coherence and economies of scale. The direct and active management of the computing resources of public Cloud 105 is performed by the computer hardware and/or software of Cloud orchestration module 131. The computing resources provided by public Cloud 105 are typically implemented by virtual computing environments that run on various computers making up the computers of host physical machine set 142, which is the universe of physical computers in and/or available to public Cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 131 manages the transfer and storage of images, deploys new instantiations of VCEs and manages active instantiations of VCE deployments. Gateway 130 is the collection of computer software, hardware, and firmware that allows public Cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public Cloud 105, except that the computing resources are only available for use by a single enterprise. While private Cloud 106 is depicted as being in communication with WAN 102, in other embodiments a private Cloud may be disconnected from the internet entirely and only accessible through a local/private network. A hybrid Cloud is a composition of multiple Clouds of different types (for example, private, community or public Cloud types), often respectively implemented by different vendors. Each of the multiple Clouds remains a separate and discrete entity, but the larger hybrid Cloud architecture is bound together by standardized or proprietary technology that enables orchestration, management, and/or data/application portability between the multiple constituent Clouds. In this embodiment, public Cloud 105 and private Cloud 106 are both part of a larger hybrid Cloud.

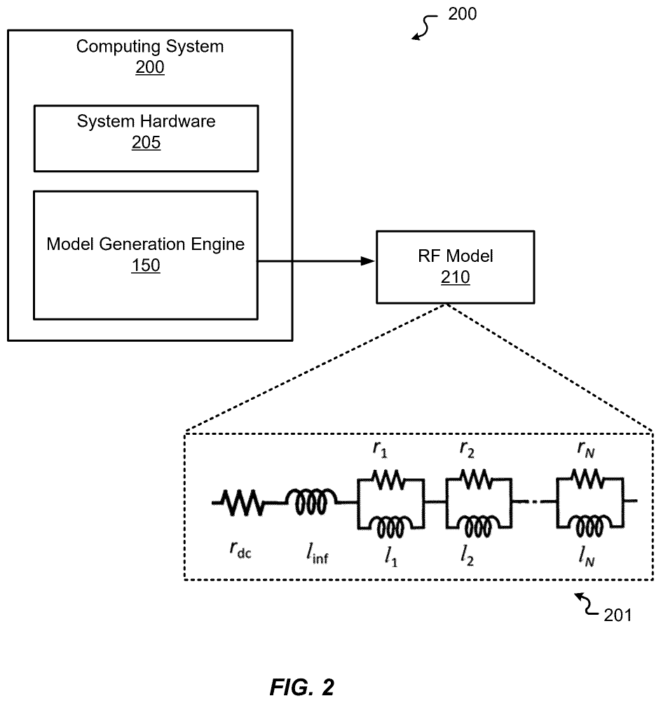

FIG. 2 illustrates a block diagram of an example computing system 200 that supports generation of accurate RF models in accordance with one or more embodiments of the present disclosure.

All or a portion of the system 200 shown in FIG. 2 can be implemented, for example, by all or a subset of the computing environment 100 of FIG. 1. In one or more embodiments, the computing system 200 is embodied in a computer 101 as the one shown in FIG. 1. In one or more embodiments, the computing system 200 is embodied in an end user device 103 as the one shown in FIG. 1.

The computing system 200 includes system hardware 205. The system hardware 205 includes the central processing units (CPUs), graphical processing units (GPUs), memory, and the like that are part of the computing system. The system hardware 205 executes computer code stored at a memory (e.g., volatile memory 112, persistent storage 113, storage 124, and the like described with reference to FIG. 1) of the computing system 200.

The computing system 200 may be integrated with or be electrically coupled to a user interface 223. User interface 223 can be implemented by device set 123 of FIG. 1. The computing system 200 may provide (e.g., visually, audibly, and the like) instruction data 235 of a user manual via the user interface 223.

The computing system 200 may include or implement the model generation engine 150. Systems and techniques described herein supportive of generation of accurate RF models as described herein may be implemented by the computing environment 100, computer 101, model generation engine 150, and computing system 200. Example aspects of the techniques described herein are described with reference to computing system 200.

For example, the computing system 200 is capable of generating an RF model 210 representative of a passive circuit 201, example aspects of which are described herein.

### SPICE Representation of Frequency-Dependent Resistance and Inductance Curves

According to one or more embodiments of the present disclosure, the computing system 200 may support generating a SPICE representation of frequency-dependent resistance and inductance curves, example aspects of which are described herein.

For a transmission line system, the computing system 200 may obtain a set of frequency-dependent impedance target values. In an example, the computing system 200 may obtain the set of frequency-dependent impedance target values through either a field solver simulation (e.g., an equivalent input disturbance (EID) solver) or an on-chip measurement using scattering parameters. For resistance and inductance values obtained through a field solver simulation, embodiments of the present disclosure may include returning an impedance matrix by such a field solver at each simulated frequency point. In an example of a 2×2 impedance matrix, Z₁₁=R₁₁+jωL₁₁, Z₂₂=R₂₂+jωL₂₂, Z₁₂=R₁₂+jωL₁₂, and Z₂₁=Z₁₂.

To simulate the transient behavior of signal delay, signal slew, signal noise coupling, or other signal characteristics, a passive SPICE model may be used by circuit designers. A passive SPICE model is desired which is capable of reproducing simulated/measured frequency-dependent impedance values as accurately as possible in the frequency domain. Some passive SPICE models use a series connection of parallel RL elements, where each parallel RL element consists of a resistive element and an inductive element connected in parallel.

The techniques described herein support matching given resistance and inductance target values at N high-frequency points as closely as possible (e.g., within a target tolerance) and, at the same time, letting the SPICE model represent other simulated/measured high-frequency impedance targets naturally. According to one or more embodiments of the present disclosure, regarding the SPICE model, the computing system 200 may build a passive circuit 201 (e.g., an RL network) for both transient simulation (i.e., in the time domain) and frequency-domain simulation. When used in the frequency-domain, the SPICE model may reproduce given target resistance and inductance values accurately. The passive circuit 201 may include a resistive element r_{dc}, an inductive element l_{inf}, and N parallel RL elements (r₁∥l₁), (r₂∥l₂), . . . , (r_{N}∥l_{N}) connected in series (FIG. 2), where the notation (rₙ∥lₙ) stands for a resistive element rₙ and an inductive element lₙ connected in parallel.

In some examples, the quantity N of parallel RL elements may be a quantity (e.g., N is 3, 4, or 5) which supports reduced SPICE simulation time. However, embodiments of the present disclosure are not limited thereto, and the quantity N may be any quantity supportive of aspects of the present disclosure.

Examples of determining the N values r₁, r₂, . . . , r_{N} of N resistive elements and the N values l₁, l₂, . . . , l_{N} of N inductive elements as well as two additional circuit elements r_{dc} and l_{inf} in accordance with one or more embodiments of the present disclosure as described herein. In association with determining the values, the computing system 200 may match DC resistance value R_{dc}, low-frequency inductance value L_{dc}, and N pairs of high-frequency resistance and inductance values (R₁, L₁), (R₂, L₂), . . . , (R_{N}, L_{N}) at N frequencies f₁, f₂, . . . , f_{N}. When a field solver is used, (R₁, L₁), (R₂, L₂), . . . , (R_{N}, L_{N}) may include any one of the following: Z₁₂ at N frequencies f₁, f₂, . . . , f_{N}, Z₁₁ at N frequencies f₁, f₂, . . . , f_{N}, Z₂₂ at N frequencies f₁, f₂, . . . , f_{N}, (Z₁₁-Z₁₂) at N frequencies f₁, f₂, . . . , f_{N}, or (Z₂₂-Z₁₂) at N frequencies f₁, f₂, . . . , f_{N}.

In terms of angular frequency ω=2πf, the frequency-dependent resistance of the passive circuit 201 may be expressed by equation (1):

$$r ( ω ) = {r}_{d c} + {\sum }_{m = 1}^{N} {r}_{m} \frac{{ω}^{2} {l}_{m}^{2}}{{r}_{m}^{2} + {ω}^{2} {l}_{m}^{2}} , \qquad ( 1 )$$

and the frequency-dependent inductance of the passive circuit 201 may be expressed by equation (2):

$$l ( ω ) = {l}_{inf} + {\sum }_{m = 1}^{N} {l}_{m} \frac{{r}_{m}^{2}}{{r}_{m}^{2} + {ω}^{2} {l}_{m}^{2}} . \qquad ( 2 )$$

At the beginning, there are (2+2N) unknowns, r_{dc}, l_{inf}, r₁, . . . , r_{N}, l₁, . . . , l_{N}, in the resistance and inductance expressions (1) and (2) associated with the passive circuit 201.

At DC (ω=0) or at low frequency, the resistance value r(ω=0) from the circuit is matched to the given DC resistance target R_{dc}. Since equation (1) reduces to r(0)=r_{dc}, the value of resistive element r_{dc} is found to be

$${r}_{d c} = {R}_{d c} . \qquad ( 3 )$$

Similarly, at DC (ω=0) or at low frequency, the inductance value l(ω=0) from the circuit is matched to the given low-frequency inductance target L_{dc}. Since equation (2) reduces to

$$l ( 0 ) = {l}_{inf} + {\sum }_{m = 1}^{N} {l}_{m} ,$$

the techniques described herein may include determining the value of inductive element l_{dc} after the values of other inductive elements l₁, l₂, . . . , l_{N} are determined through equation (4),

$${l}_{inf} = {L}_{d c} - {\sum }_{m = 1}^{N} {l}_{m} . \qquad ( 4 )$$

Per equation (4), the inductance at infinite frequency l_{inf} is smaller than low-frequency inductance L_{dc}.

Substituting equation (3) into equation (1), one unknown (r_{dc}) is eliminated from the resistance expression of the passive circuit 201,

$$r ( ω ) = {R}_{dc} + {\sum }_{m = 1}^{N} {r}_{m} \frac{{ω}^{2} {l}_{m}^{2}}{{r}_{m}^{2} + {ω}^{2} {l}_{m}^{2}} . \qquad ( 5 )$$

Substituting equation (4) into equation (2), another unknown (l_{inf}) is eliminated from the inductance expression of the passive circuit 201,

$$l ( ω ) = {L}_{dc} - {\sum }_{m = 1}^{N} {l}_{m} \frac{{ω}^{2} {l}_{m}^{2}}{{r}_{m}^{2} + {ω}^{2} {l}_{m}^{2}} . \qquad ( 6 )$$

Setting ω=0 in the resistance expression (5) of the passive circuit 201, it is clear that the given DC resistance target R_{dc} is always precisely represented. Similarly, setting ω=0 in the inductance expression (6) of the passive circuit 201, it is clear that the given low-frequency inductance target L_{dc} is also always precisely represented. At this stage, there are 2N unknowns r₁, . . . , r_{N}, l₁, . . . , l_{N} in the resistance and inductance expressions (5) and (6) of the 201. At N angular frequencies ωn=2πfₙ (n=1, 2, . . . , N), N resistance values from the circuit may be represented by equation (7):

$$r ( {ω}_{n} ) = {R}_{dc} + {\sum }_{m = 1}^{N} {r}_{m} \frac{{ω}_{n}^{2} {l}_{m}^{2}}{{r}_{m}^{2} + {ω}_{n}^{2} {l}_{m}^{2}} , n = 1 , 2 , … , N , \qquad ( 7 )$$

and N inductance values from the circuit may be represented by equation (8):

$$l ( {ω}_{n} ) = {L}_{dc} - {\sum }_{m = 1}^{N} {l}_{m} \frac{{ω}_{n}^{2} {l}_{m}^{2}}{{r}_{m}^{2} + {ω}_{n}^{2} {l}_{m}^{2}} , n = 1 , 2 , … , N . \qquad ( 8 )$$

The computing system 200 may obtain 2N nonlinear equations (9a) and (9b) for 2N unknowns, r₁, r₂, . . . , r_{N}, and l₁, l₂, . . . , l_{N}.

$$Δ {R}_{n} = 0 , n = 1 , 2 , … , N ; \qquad ( 9 a )$$

$$Δ {L}_{n} = 0 , n = 1 , 2 , … , N ; \qquad ( 9 b )$$

$$where$$

$$Δ {R}_{n} ≡ r ( {ω}_{n} ) - {R}_{n} , n = 1 , 2 , … , N ; \qquad ( 9 c )$$

$$Δ {L}_{n} ≡ l ( {ω}_{n} ) - {L}_{n} , n = 1 , 2 , … , N . \qquad ( 9 d )$$

Some approaches may find 2N unknowns, r₁, r₂, . . . , r_{N} and l₁, l₂, . . . , l_{N}, simultaneously, through various kinds of search in a 2N-dimensional space: (r₁, r₂, . . . , r_{N}, and l₁, l₂, . . . , l_{N}). Due to the nonlinear nature of equations (9a) and (9b), some approaches for finding a set of solutions may minimize a combination of ΔR₁, ΔR₂, . . . , ΔR_{N}, ΔL₁, ΔL₂, . . . , ΔL_{N}. For example, some approaches may minimize this cost function for a sum of squares of both resistance residuals and inductance residuals, using equation (10):

$${S}_{RL} = {\sum }_{n = 1}^{N} [ {( \frac{Δ {R}_{n}}{{R}_{n}} )}^{2} + {( \frac{Δ {L}_{n}}{{L}_{n}} )}^{2} ] , \qquad ( 10 )$$

whose minimum value is zero.

### Matching N Resistance Targets Exactly

According to one or more embodiments of the present disclosure, the computing system 200 may find 2N unknowns, r₁, r₂, . . . , r_{N} and, l₁, l₂, . . . , l_{N}, through a search in an N-dimensional space while satisfying a set of N relations (9a) (e.g., such that the set of N relations (9a) is always satisfied) during a search/minimization process. For any search result provided by the computing system 200, i.e., independent of inductance fitting quality, N given resistance values are always matched exactly (e.g., within a target tolerance or target accuracy).

Embodiments of the present disclosure include introducing (or implementing) a coordinate transformation: Another set of 2N variables is introduced to replace N circuit resistive values and N circuit inductive values. Specifically, embodiments of the present disclosure include introducing a newly constructed “amplitude” and “phase” system in which there are N amplitudes ρ₁, ρ₂, . . . , ρ_{N} and N phases φ₁, φ₂, . . . , φ_{N},

$${r}_{m} = {ρ}_{m} cos {φ}_{m} , {ω}_{m} {l}_{m} = {ρ}_{m} sin {φ}_{m} , 0 < {φ}_{m} < \frac{1}{2} π , m = 1 , 2 , … , N . \qquad ( 11 )$$

Embodiments of the present disclosure include representing the resistance expression (7) of the passive circuit 201 in the amplitude-phase coordinate system, resulting that each of the N resistance values for the passive circuit 201 is a linear combination of N amplitudes ρ₁, ρ₂, . . . , ρ_{N}, as represented by equation (12):

$$r ( {ω}_{n} ) = {R}_{dc} + {\sum }_{m = 1}^{N} ( {p}_{n , m} cos {φ}_{m} ) {ρ}_{m} , n = 1 , 2 , … , N , \qquad ( 12 )$$

$$where$$

$${p}_{n , m} ( {φ}_{m} ) = \frac{{ω}_{n}^{2} {sin}^{2} {φ}_{m}}{{ω}_{m}^{2} {cos}^{2} {φ}_{m} + {ω}_{n}^{2} {sin}^{2} {φ}_{m}} , n , m = 1 , 2 , … , N . \qquad ( 13 )$$

Representing the inductance expression (8) of the passive circuit 201 in the amplitude-phase coordinate system, each of the N inductance values for the passive circuit 201 is a linear combination of N amplitudes ρ₁, ρ₂, . . . , ρ_{N}, as given by equation (14):

$$l ( {ω}_{n} ) = {L}_{dc} + {\sum }_{m = 1}^{N} ( {p}_{n , m} \frac{sin {φ}_{m}}{{ω}_{m}} ) {ρ}_{m} , n = 1 , 2 , … , N . \qquad ( 14 )$$

Given a set of N phases φ₁, φ₂, . . . , φ_{N}, nonlinear equation (9a) for N resistance values becomes a set of N linear algebraic equations for N amplitudes ρ₁, ρ₂, . . . , ρ_{N} in equation (12), and embodiments of the present disclosure include solving the N linear algebraic equations (12) exactly and expressing the solution for N amplitudes ρ₁, ρ₂, . . . , ρ_{N} in a function form:

$${ρ}_{m} = {f}_{m} ( {φ}_{1} , {φ}_{2} , … , {φ}_{N} ) , m = 1 , 2 , … , N . \qquad ( 15 )$$

The terms “equation,” “solution,” “relation,” and “solution expression” may be used interchangeably herein.

Solution expression (15) shows that N amplitudes ρ₁, ρ₂, . . . , ρ_{N} have been expressed as a set of functions of N phases φ₁, φ₂, . . . , φ_{N}. Through equations (14) and (9d), substituting solution expression (15) into inductance equation (9b) leads to a reduced set of N relations for N phases, φ₁, φ₂, . . . , φ_{N} that are to be matched:

$$Δ {L}_{n} ≡ {L}_{dc} - {\sum }_{m = 1}^{N} ( {p}_{n , m} \frac{sin {φ}_{m}}{{ω}_{m}} ) {f}_{m} ( {φ}_{1} , {φ}_{2} , … , {φ}_{N} ) - {L}_{n} = 0 , n = 1 , 2 , … , N . \qquad ( 16 )$$

The deriving of an equation herein based on a prior equation may be referred to herein as transforming the prior equation.

Since equation (9a) is already satisfied here (through the usage of solution expression (15)), the original “cost” function (equation (10)) reduces to a sum of squares of inductance residuals, which may be represented by a non-negative function (17):

$${S}_{L} = {\sum }_{n = 1}^{N} {( \frac{Δ {L}_{n}}{{L}_{n}} )}^{2} . \qquad ( 17 )$$

In other words, instead of searching for a best fit in a 2N-dimensional space (r₁, r₂, . . . , r_{N}, l₁, l₂, . . . , r_{N}), embodiments of the present disclosure include searching for a best fit in an N-dimensional phase space (φ₁, φ₂, . . . , ρ_{N}). After obtaining a set of best-fit for N phases φ₁, φ₂, . . . , ρ_{N}, the techniques described herein may include using solution expression (15) again to obtain a set of corresponding N amplitudes ρ₁, ρ₂, . . . , ρ_{N}. After obtaining a set of N phases φ₁, φ₂, . . . , φ_{N} and a corresponding set of N amplitudes ρ₁, ρ₂, . . . , ρ_{N}, the techniques described herein may include using coordinate transformation relation (11) again to obtain a set of values for N resistive elements r₁, r₂, . . . , ᵣN and also for N inductive elements l₁, l₂, . . . , l_{N}. Lastly, the techniques described herein may include obtaining the value of inductive element l_{inf} (representing the asymptotic inductance value of the circuit at infinite frequency) through relation (4) and obtaining the value of resistive element r_{dc} through relation (3). In some aspects, a slightly different set of N phases φ₁, φ₂, . . . , φ_{N} may change the degree that equation (16) and equation (9b) are satisfied and may also first lead to a slightly different set of N amplitudes, ρ₁, ρ₂, . . . , ρ_{N}, and then lead to a slightly different set of values for N resistive elements r₁, r₂, . . . , r_{N} and for N inductive elements l₁, l₂, . . . , l_{N}, but equation (6a) are always accurately satisfied.

An example case is described herein where 3 parallel RL elements are constructed (e.g., r₁, r₂, r₃, l₁, l₂, l₃). For a brute-force search of 100 points in each variable, searching for a best fit in an N-dimensional phase space in accordance with one or more embodiments of the present disclosure may reduce the quantity search points from 10¹² (one trillion) to 10⁶ (one million). For a first-round coarse search of 10 points in each variable (a second-round refined search will start from the best point found from the first-round search), searching for a best fit in an N-dimensional phase space in accordance with one or more embodiments of the present disclosure may reduce the quantity of search points from one million to one thousand. For any search solution provided in accordance with the techniques described herein, whether the solution for inductance satisfies solution criteria accurately or less accurately, N given resistance values are always matched exactly. More importantly, for any search solution (any set of phase solutions) provided in accordance with the techniques described herein, N given resistance targets (i.e., all N resistance targets) are always matched exactly.

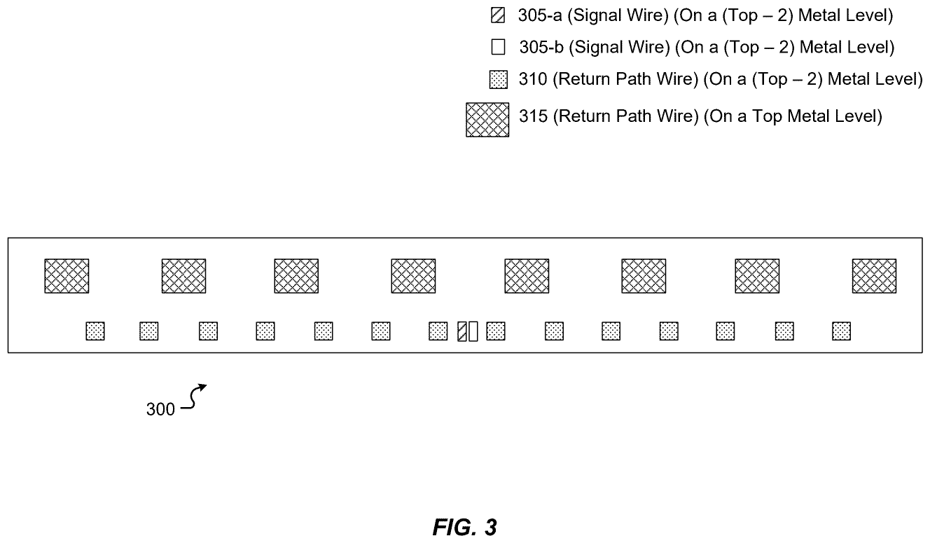

FIG. 3 illustrates an example view of a cross section of a group of wires included in a power distribution network 300. Two signal wires 305 (wire 305-a, wire 305-b) are at the middle of a lower metal level. 14 wires 310 at the lower metal level are a part of return-path wires. 8 wires 315 (relatively thick compared to wires 305 and wires 310) located at an upper metal level are the rest of return-path wires.

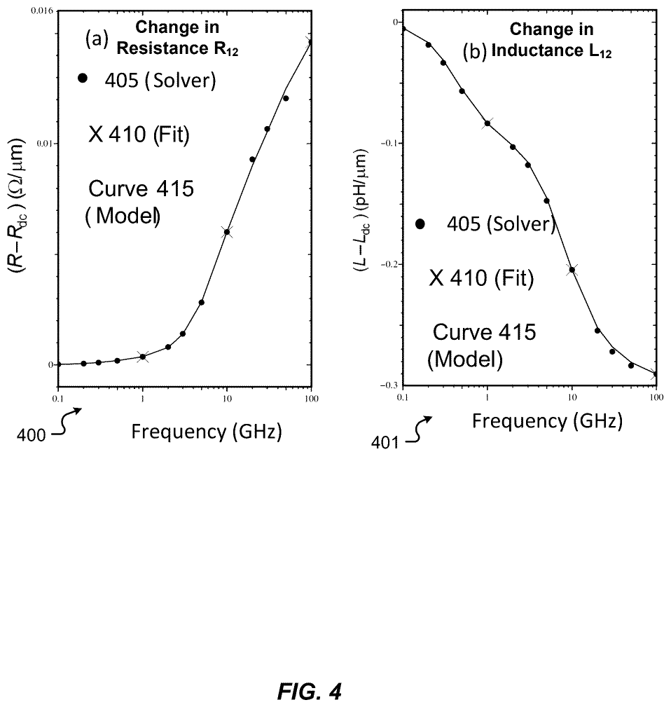

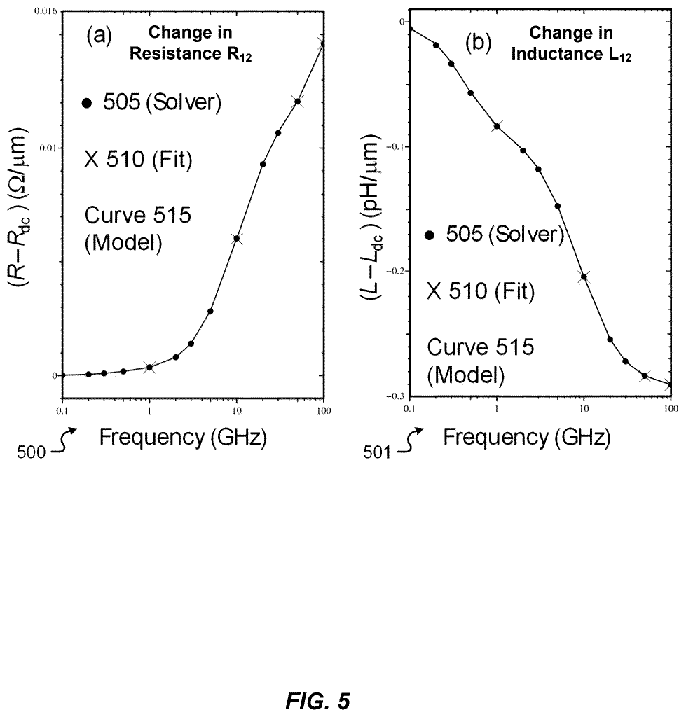

Aspects of fitting or matching in accordance with one or more embodiments of the present disclosure are described with reference to FIGS. 3 through 5. FIGS. 4 and 5 illustrate an example of fitting quality of the method for generation of accurate RF models in accordance with one or more embodiments of the present disclosure.

To study a power distribution network, two signal wires 305 (e.g., signal wire 305-a, signal wire 305-b) and a group of widely spaced return-current-path wires form a loop in this example. The group of return-current-path wires consists of 14 power-grid wires 310 at the same metal level as the signal wires 305 and 8 power-grid wires 315 (of a significantly greater thickness than the power-grid wires 310) located two metal levels above the signal wires 305.

Embodiments of the present disclosure include generating, by a field solver, a 2×2 impedance matrix at each of multiple simulated frequency points. The Z₁₂ element (Z₁₂=R₁₂+jωL₁₂) in the 2×2 impedance matrix exhibits much greater percentage changes than both Z₁₁ and Z₂₂ elements (Z₁₁=R₁₁+jωL₁₁, Z₂₂=R₂₂+jωL₂₂) in the matrix when frequency is increased from low to high. The greater percentage changes are due to the proximity effect in the return-current-path wires between which the spaces are relatively wide compared to the space between the signal wire 305-a and signal wire 305-b. As shown at FIG. 4, inductance decreases relatively quickly between 0.2 and 0.5 GHZ, relatively slowly from 0.5 GHz to 3 GHZ, and again decreases relatively quickly between 3 and 10 GHz. Using 3 parallel RL elements (e.g., setting N equal to 3, such that passive circuit 201 includes r₁ and l₁, r₂ and l₂, r₃ and l₃) in the example power distribution network 300, embodiments of the present disclosure provide a model capable of accurately capturing such a behavior of two rounds of a relatively quick drop in inductance.

FIG. 4 illustrates example plots 400 and 401 of frequency-dependent (a) resistance (ReZ₁₂) and (b) inductance (ImZ₁₂/ω) of a power distribution network (e.g., power distribution network 300), which consists of two signal wires 305 and a group of return-current-path wires (wires 310 and wires 315) that form a loop. The plots 400 and 401 illustrate results provided by a field solver, exact fitting/solving of resistance or inductance in accordance with one or more embodiments of the present disclosure, and approximate (predicted) fitting/solving of resistance or inductance in accordance with one or more embodiments of the present disclosure.

Black diamonds 405 indicate field solver simulated impedance values. Embodiments of the present disclosure include selecting a quantity of frequency values for fitting. For example, with reference to FIG. 4, three sets of high-frequency impedance values at 1 GHz, 10 GHz, and 100 GHz and a low-frequency (100 Hz) impedance value are selected for fitting.

Circles 410 indicate solver results matched for resistance exactly and, in this example, also for inductance exactly at 1 GHz, 10 GHz, and 100 GHz in accordance with one or more embodiments of the present disclosure. Circles 415 indicate impedance values (and resistance values) as predicted by a model at other points in accordance with one or more embodiments of the present disclosure.

In an example, embodiments of the present disclosure include using field solver generated R and L values at 1 GHz, 10 GHz, and 100 GHz to do fitting. At each of 1 GHz, 10 GHz, and 100 GHz, embodiments of the present disclosure include matching solver and fit R values exactly (plot 400). R and L values provided by the model at several other frequences are also shown.

FIG. 5 illustrates example plots 500 and 501 of frequency-dependent (a) resistance (ReZ₁₂) and (b) inductance (ImZ₁₂/ω) of the same power distribution network as described with reference to FIG. 4.

Black diamonds 505 indicate field solver simulated impedance values. Embodiments of the present disclosure include selecting a quantity of frequency values for fitting. For example, with reference to FIG. 5, four sets of high-frequency impedance values at 1 GHz, 10 GHz, 50 GHz, and 100 GHz and a low-frequency (100 Hz) impedance value are selected for fitting. Circles 510 indicate solver results matched for resistance exactly and, in this example, also for inductance exactly at 1 GHz, 10 GHZ, and 100 GHz in accordance with one or more embodiments of the present disclosure. Circles 415 indicate impedance values as predicted by a model at other points in accordance with one or more embodiments of the present disclosure.

### Matching N Inductance Targets Exactly

According to one or more embodiments of the present disclosure, the computing system 200 may find 2N unknowns, r₁, r₂, . . . , r_{N} and l₁, l₂, . . . , l_{N}, through a search in an N-dimensional space while maintaining a set of N relations (9b) (e.g., such that the set of N relations (9b) is always maintained) during the search/minimization process. For any search result provided by the computing system 200, i.e., independent of resistance fitting quality, N given inductance values are always matched exactly (e.g., within a target tolerance or target accuracy).

Recall equation (14) above. Given a set of N phases φ₁, φ₂, . . . , φ_{N}, equation (9b) for N inductance values becomes a set of N linear algebraic equations for N amplitudes ρ₁, ρ₂, . . . , ρ_{N} in equation (14). Embodiments of the present disclosure includes solving equation (14) exactly and expressing the solution for N amplitudes ρ₁, ρ₂, . . . , ρ_{N} in another function form:

$${ρ}_{m} = {g}_{m} ( {φ}_{1} , {φ}_{2} , … , {φ}_{N} ) , m = 1 , 2 , … , N . \qquad ( 18 )$$

Solution (18) shows that N amplitudes ρ₁, ρ₂, . . . , ρ_{N} have been expressed as another set of functions of N phases φ₁, φ₂, . . . , φ_{N}. Embodiments of the present disclosure include substituting solutions expression (18) into resistance equations (9a). Through equation (12) and (9c), this leads to another set of N relations for N unknown phases, φ₁, φ₂, . . . , φ_{N}, that are to be matched:

$$Δ {R}_{n} ≡ {R}_{dc} + {\sum }_{m = 1}^{N} ( {p}_{n , m} cos {φ}_{m} ) {g}_{m} ( {φ}_{1} , {ϕ}_{2} , … , {φ}_{N} ) - {R}_{n} = 0 , m = 1 , 2 , … , N . \qquad ( 19 )$$

Similarly, embodiments of the present disclosure include searching for a best fit in an N-dimensional phase space (φ₁, φ₂, . . . , φ_{N}). As equation (9b) is already satisfied here (through the usage of solution expression (18)), the original “cost” function of equation (10) reduces to a sum of squares of resistance residuals, which may be represented by another non-negative function (20).

$${S}_{R} = {\sum }_{n = 1}^{N} {( \frac{Δ {R}_{n}}{{R}_{n}} )}^{2} . \qquad ( 20 )$$

Namely, instead of searching for a best fit in a 2N-dimensional space (r₁, r₂, . . . , r_{N}, l₁, l₂, . . . , l_{N}), embodiments of the present disclosure include searching for a best fit in an N-dimensional phase space (φ₁, φ₂, . . . , φ_{N}). After obtaining a set of best-fit N phases φ₁, φ₂, . . . , φ_{N}, the techniques described herein may include using solution expression (18) to obtain a set of corresponding N amplitudes ρ₁, ρ₂, . . . , ρ_{N}. After obtaining a set of N phases φ₁, φ₂, . . . , φ_{N} and a corresponding set of N amplitudes ρ₁, ρ₂, . . . , ρ_{N}, the techniques described herein may include using coordinate transformation relation (11) to obtain a set of values for N resistive elements r₁, r₂, . . . , r_{N} and also for N inductive elements l₁, l₂, . . . , l_{N}. Lastly, the techniques described herein may include obtaining the value of inductive element l_{inf} (representing the asymptotic inductance value of the circuit at infinite frequency) through relation (4) and obtaining the value of resistive element r_{dc} through relation (3). In some aspects, a slightly different set of N phases φ₁, φ₂, . . . , φ_{N} may change the degree that equation (19) and equation (9a) are satisfied and may also first lead to a slightly different set of N amplitudes, ρ₁, ρ₂, . . . , ρ_{N}, and then lead to a slightly different set of values for N resistive elements r₁, r₂, . . . , r_{N} and for N inductive elements l₁, l₂, . . . , l_{N}, but equation (9b) are always accurately satisfied.

An example is again described herein for a case in which there are 3 parallel RL elements. For a brute-force search of 100 points in each variable, searching for a best fit in an N-dimensional phase space in accordance with one or more embodiments of the present disclosure reduces the search points from 10¹² (one trillion) to 10⁶ (one million). For a first-round coarse search of 10 points in each variable (a second-round refined search will start from the best point found in the first-round search), searching for a best fit in an N-dimensional phase space reduces the search points from one million to one thousand. For any search solution provided in accordance with the techniques described herein, whether satisfying search criteria or failing to satisfy the solution criteria, N given inductance targets (values) (e.g., all N inductance targets) are always matched exactly.

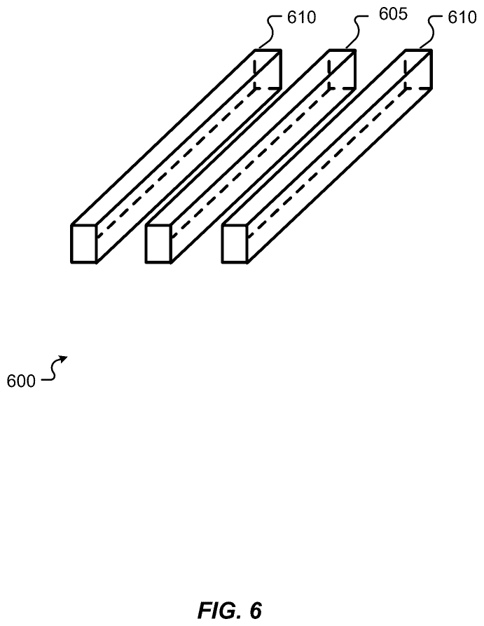

FIG. 6 illustrates an example of a single coplanar waveguide (CPW) structure 600 used in some VLSI chips. Aspects of applying an accurate model in accordance with one or more embodiments of the present disclosure are described with reference to FIGS. 6 through 8.

An example is described herein with reference to the CPW structure 600, in which N inductance targets are matched exactly. The structure 600 includes a long signal wire 605 (e.g., in one of two topmost metal levels) placed between two return-current-path wires 610 which are adjacent or nearby the signal wire 605.

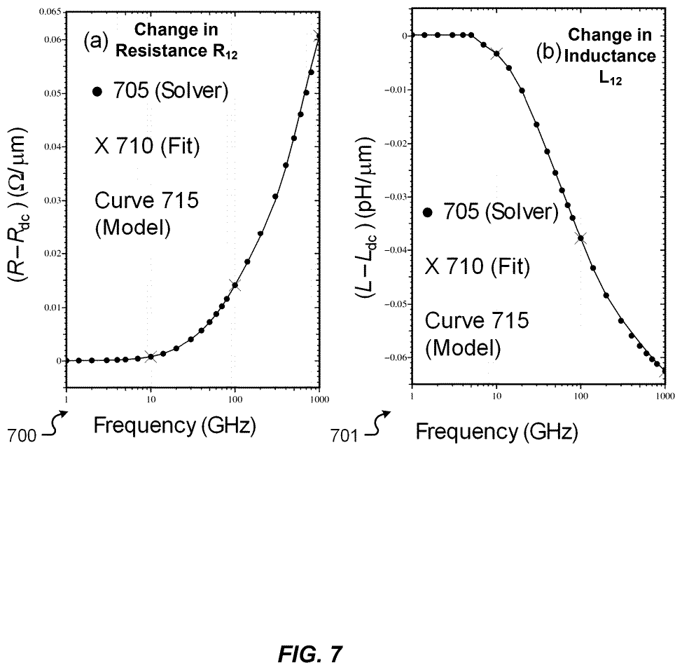

Embodiments of the present disclosure include producing or generating, by a field solver, a loop resistance value and a loop inductance value at each of multiple simulated frequency points (illustrated at FIG. 7). Different from the power distribution network described with reference to FIGS. 3 through 5, there is no proximity effect (but there is still the skin effect), and inductance starts to decrease only at frequencies higher than 5 GHz.

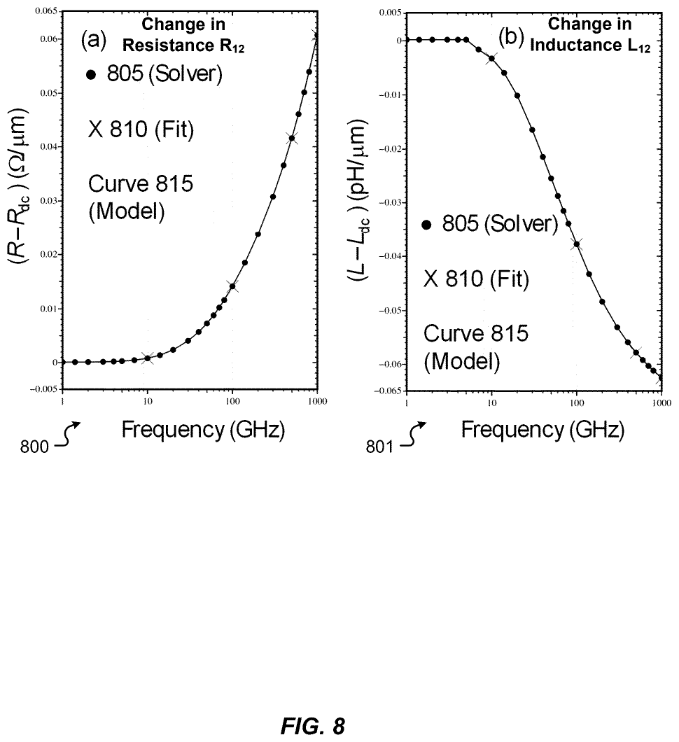

In the example structure 600, as seen by the plots described with reference to FIGS. 7 and 8, there is one round of inductance quick drop.

FIG. 7 illustrates example plots 700 and 701 of frequency-dependent (a) loop resistance (ReZ) and (b) loop inductance (ImZ/ω) of a single CPW structure (e.g., CPW structure 600), which consists of a signal wire 605 placed between two return-current-path wires 610 that form a loop. The plots 700 and 701 illustrate results provided by a field solver, exact fitting/solving of resistance or inductance in accordance with one or more embodiments of the present disclosure, and approximate (predicted) fitting/solving of resistance or inductance in accordance with one or more embodiments of the present disclosure.

FIG. 7 is an example of results associated with using 3 parallel RL elements (e.g., setting N equal to 3, such that passive circuit 201 includes r₁ and l₁, r₂ and l₂, r₃ and l₃) in modeling the example structure 600. As seen with reference to FIG. 7, the model in accordance with one or more embodiments of the present disclosure is capable of accurately capture global behavior of both resistance and inductance versus frequency, and especially at high frequencies (e.g., frequencies equal to or greater than 10 GHz).

Black diamonds 705 indicate field solver simulated impedance values. Embodiments of the present disclosure include selecting a quantity of frequency values for fitting. For example, with reference to FIG. 7, three sets of high-frequency impedance values at 1 GHz, 10 GHz, and 100 GHz and a low-frequency (100 Hz) impedance value are selected for fitting.

Circles 710 indicate solver results matched for inductance exactly and, in this example, also for resistance exactly at 1 GHz, 10 GHz, and 100 GHz in accordance with one or more embodiments of the present disclosure. Circles 715 indicate impedance values (and resistance values) as predicted by a model at other points in accordance with one or more embodiments of the present disclosure.

FIG. 8 illustrates example plots 800 and 801 of frequency-dependent (a) loop resistance (ReZ) and (b) loop inductance (ImZ/ω) of the single CPW structure (e.g., CPW structure 600) described with reference to FIGS. 6 and 7. The plots 800 and 801 illustrate results provided by a field solver, exact fitting/solving of resistance or inductance in accordance with one or more embodiments of the present disclosure, and approximate (predicted) fitting/solving of resistance or inductance in accordance with one or more embodiments of the present disclosure.

FIG. 8 is an example of results associated with using 4 parallel RL elements (e.g., setting N equal to 4, such that passive circuit 201 includes r₁ and l₁, r₂ and l₂, r₃ and l₃, r₄ and l₄) in modeling the example structure 600. As seen with reference to FIG. 8, the model in accordance with one or more embodiments of the present disclosure is capable of accurately capture global behavior of both resistance and inductance versus frequency

Black diamonds 805 indicate field solver simulated impedance values. Embodiments of the present disclosure include selecting a quantity of frequency values for fitting. For example, with reference to FIG. 7, four sets of high-frequency impedance values at 10 GHz, 100 GHz, 500 GHz, and 1000 GHz and a low-frequency (100 Hz) impedance value are selected for fitting.

Circles 810 indicate solver results matched for inductance exactly and, in this example, also for resistance exactly at 10 GHz, 100 GHz, 500 GHz, and 1000 GHz in accordance with one or more embodiments of the present disclosure. Circles 815 indicate impedance values (and resistance values) as predicted by a model at other points in accordance with one or more embodiments of the present disclosure.

Comparing FIG. 8 to FIG. 7, it can be seen that, as more data points are used for fitting, values generated by the model at other frequency points which are not used for fitting move toward field solver generated values (e.g., impedance values, inductance values, based on implementation).

Embodiments of the present disclosure support further optimizing equations (17) and (20) using well known algorithms suitable for model fitting described herein. Examples of further optimizing equations (17) and (20) are now described herein.

As has been described herein, embodiments of the present disclosure provide a system and method of developing an accurate RL model for SPICE simulation of transient signals. Given a pair of frequency-dependent resistance and inductance target curves for a transmission line system or for a CPW device, the system and method may generate a passive device model for transient SPICE simulations with increased accuracy and reduced processing overhead (e.g., by reducing the number of search points as described herein) compared to some other approaches.

FIGS. 4, 5, 7, and 8 demonstrate the value of the model supported by aspects of the present disclosure by illustrating two practical use cases. In an example, embodiments of the present disclosure support, when one parallel RL element is used to match high-frequency resistance and inductance values at one frequency point, obtaining the exact and analytic solution of resistive and inductive elements used in a passive circuit. With a migration to backside power distribution technology, modeling approaches supported by aspects of the present disclosure are capable of providing improved (e.g., increased accuracy) delay predictions for long paths, which may reduce reliance on difficult hardware diagnosis of speed paths in the presence of wiring on both sides of a chip.

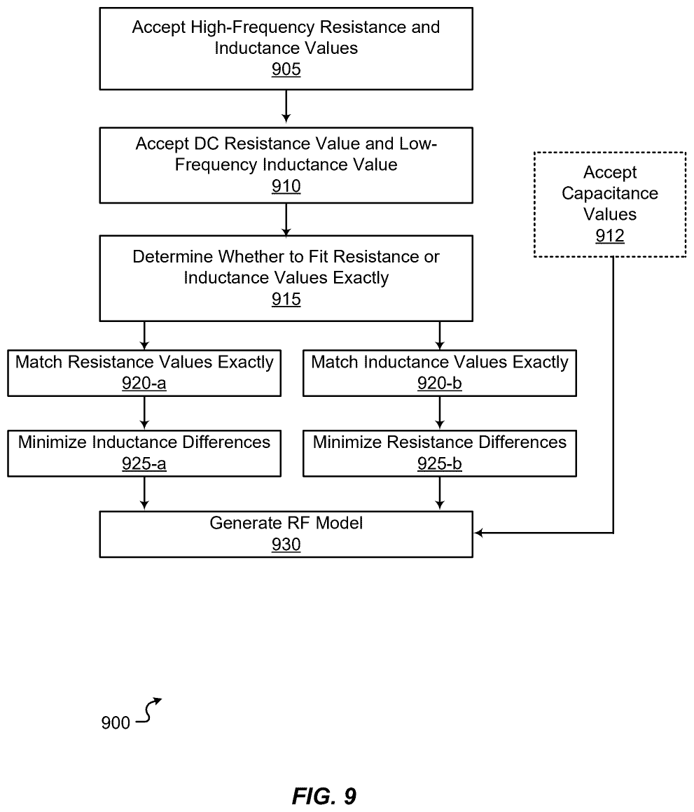

FIG. 9 illustrates an example flowchart of a method 900 in accordance with one or more embodiments of the present disclosure. The method 900 may be implemented by the example aspects of a computing environment 100 or a computing system 200 (e.g., an RF model generating system) as described herein with reference to passive circuit 201.

The method 900 includes a fitting procedure which may generate an RF model corresponding to a device (e.g., passive circuit 201, power distribution network 300, or CPW structure 600) in accordance with one or more embodiments of the present disclosure.

At 905, the method 900 may include obtaining a set of high-frequency resistance values and inductance values for N pairs of resistors (e.g., r₁ through r_{N}) and inductors (e.g., l₁ through l_{N}) of a device. The device may be a set of interconnect wires (e.g., as described with reference to power distribution network 300 of FIG. 3) or a CPW device (e.g., CPW structure 600 described with reference to FIG. 6).

For example, at 905, the method 900 may include obtaining or accepting a set of N pairs (resistance, inductance) values at N frequencies f₁, f₂, . . . , f_{N} of the device. In some embodiments, the N frequencies may be relatively high frequencies (e.g., 10 GHz or higher). The resistance and inductance values obtained or accepted at 905 may also referred to herein as initial resistance values and initial inductance values.

At 910, the method 900 may include obtaining (accepting) a DC resistance value R_{dc} and a low-frequency/DC inductance value L_{inf} of the device. The low-frequency may be, for example, from a few Hz to 1 MHz.

In some embodiments, at 912, the method 900 may include obtaining (accepting) a set of capacitance values of the device and the length of wires (or of the structures of the CPW structure 600) and receiving (accepting) a user input on the number of segments. The capacitance values obtained or accepted at 912 may also referred to herein as initial capacitance values. In some other embodiments, the method 900 may omit the operations described with reference to 912.

At 915, the method 900 may include determining whether to fit resistance values exactly or fitting inductance values exactly. For example, in accordance with one or more embodiments of the present disclosure, the computing system 200 allows a user to input an instruction for resistance values (e.g., for r₁ through r_{N}) to be fit exactly or for inductance values (e.g., for l₁ through l_{N}) to be fit exactly.

In an example, at 920-a, the method 900 may include matching the N resistance values exactly. At 925-a, the method 900 may include minimizing inductance differences.

For example, based on a user input instructing for the N resistance values to be matched exactly, the computing system 200 may minimize inductance differences while exactly matching resistance values. In an example, during each round of the inductance-difference minimization process, the N resistance relations are always matched exactly.

In an alternative example, at 920-b, the method 900 may include matching the N inductance values exactly. At 925-b, the method 900 may include minimizing resistance differences.

For example, based on a user input instructing for the N inductance values to be matched exactly, the computing system 200 may minimize resistance differences while exactly matching inductance values. In an example, during each round of the resistance-difference minimization process, the N inductance relations are always matched exactly.

At 930, the method 900 includes generating or building an RF model. For example, after one of the fitting and minimization processes described herein (e.g., at 920-a and 925-a, at 920-b and 925-b), the computing system 200 may generate N pairs of resistive and inductive elements (e.g., r₁ through r_{N} and l₁ through l_{N}) that are connected in parallel, plus a resistive element r_{dc} and an inductive element l_{inf}. These (N+2) elements are connected in series and form one segment of an RF model. The RF model may correspond to passive circuit 201.

Accordingly, for example, based on the example operations described with reference to 920-a and 925-a, the method 900 may include forming all segments of the RF model such that the N resistance values of r₁ through r_{N} are matched exactly and that the N inductance values of l₁ through l_{N} are matched approximately as described herein.

Alternatively, for example, based on the example operations described with reference to 920-b and 925-b, the method 900 may include forming all segments of the RF model such that the N inductance values of l₁ through l_{N} are matched exactly and that the N resistance values of r₁ through r_{N} are matched approximately as described herein.

In some embodiments, for an example case in which the method 900 includes receiving or accepting the capacitance values at 912, the method 900 may include producing an RF model (e.g., as described with reference to 915 through 930) which further includes capacitive elements in combination with the resistive and inductive elements described herein. The RF model may include R, L, and C elements and a user specified number of segments.

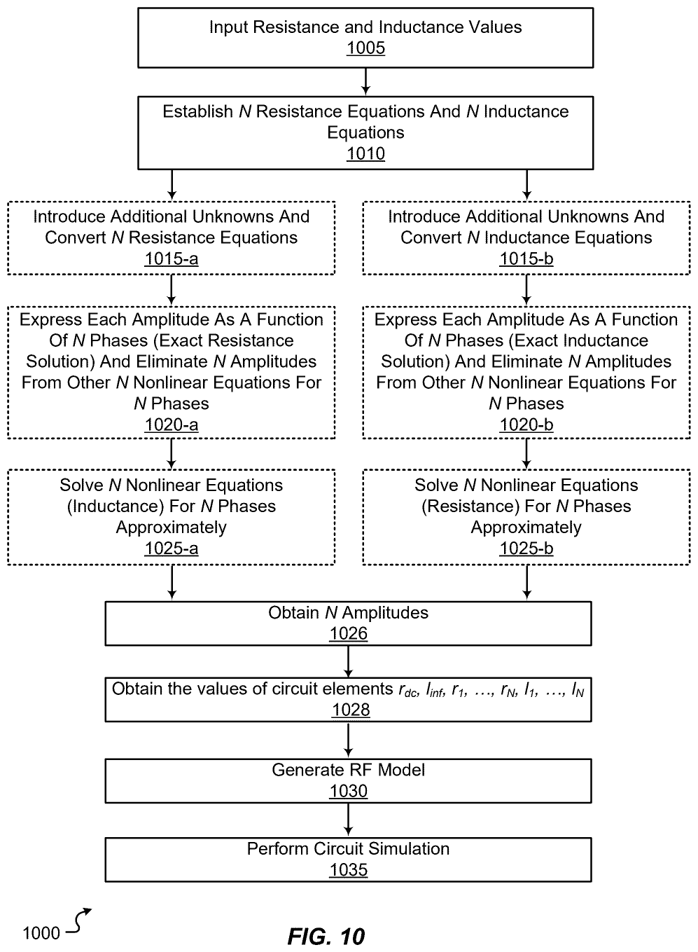

FIG. 10 illustrates an example flowchart of a method 1000 in accordance with one or more embodiments of the present disclosure. The method 1000 may be implemented by the example aspects of computing system 200 as described herein. The method 1000 includes aspects of method 900 described herein, and repeated descriptions of like elements are omitted for brevity.

At 1005, the method 1000 may include obtaining and inputting resistance and inductance values at N frequencies (also referred to herein as initial resistance values and initial inductance values). For example, at 1005, the method 1000 may include inputting R_{dc}, L_{dc}, (R₁, L₁), . . . , (R_{N}, L_{N}) at N frequencies.

At 1010, the method 1000 may include establishing N resistance equations and N inductance equations, in which, for the equations, there are 2N unknowns: (r₁, l₁), . . . , (r_{N}, l_{N}).

The method 1000 may include fitting resistance values exactly (e.g., as described with reference to 1015-a and 1020-a) and fitting inductance values approximately (e.g., as described with reference to 1025-a).

For example, at 1015-a, the method 1000 may include introducing additional unknowns and converting the N resistance equations. In an example, the method 1000 may include introducing another set of 2N unknowns (N amplitudes and N phases) and converting the N resistance equations into a set of N linear equations for N amplitudes (phases are in the coefficient).

At 1020-a, the method 1000 may include expressing each amplitude as a function of N phases (exact resistance solution for any given N phases) and eliminating N amplitudes from the other N nonlinear equations for N phases.

At 1025-a, the method 1000 may include solving the N nonlinear equations for N phases approximately. For example, the method 1000 may include solving for approximate inductance values.

Alternatively, the method 1000 may include fitting inductance values exactly (e.g., as described with reference to 1015-b and 1020-b) and fitting resistance values approximately (e.g., as described with reference to 1025-b).

For example, at 1015-b, the method 1000 may include introducing additional unknowns and converting the N inductance equations. In an example, the method 1000 may include introducing another set of 2N unknowns (N amplitudes and N phases) and converting the N inductance equations into a set of N linear equations for N amplitudes (phases are in the coefficient).

At 1020-b, the method 1000 may include expressing each amplitude as a function of N phases (exact inductance solution for any given N phases) and eliminating N amplitudes from the other N nonlinear equations for N phases.

At 1025-b, the method 1000 may include solving the N nonlinear equations for N phases approximately. For example, the method 1000 may include solving for approximate resistance values.

At 1026, the method 1000 may include obtaining N amplitudes.

At 1028, the method 1000 may include obtaining the values of resistive element r_{dc}, inductive element l_{inf}, resistive elements r₁ through r_{N}, and inductive elements l₁ through l_{N}.

At 1030, the method 1000 may include generating or building an RF model based on the solutions output by 1020-a and 1025-a (e.g., exact resistance solution, approximated inductance solution). Alternatively, at 1030, the method 1000 may include generating or building an RF model based on the solutions output by 1020-b and 1025-b (e.g., exact inductance solution, approximated resistance solution). That is, for example, the method 1000 may include generating or building an RF model based on the amplitudes obtained at 1026 and the values of resistive element r_{dc}, inductive element l_{inf}, resistive elements r₁ through r_{N}, and inductive elements l₁ through l_{N} as determined at 1028.

At 1035, the method 1000 includes performing a circuit simulation based on the RF model.

Additional example aspects of techniques and equations supportive of generation of accurate RF models through exact matching of N resistance values (resistance targets) or exact matching of N inductance values (inductance targets) in accordance with one or more embodiments of the present disclosure are further described herein. The techniques may be implemented by systems and computing devices (e.g., computing environment 100, computer 101, computing system 200, model generation engine 150) described herein. For purposes of discussion below, some equations previously expressed above are repeated, and some equations previously expressed above are modified and labeled accordingly.

Aspects of the techniques described herein differ from some other approaches which may include finding 2N unknowns (r₁, r₂, . . . , l_{N} and l₁, l₂, . . . , l_{N}) simultaneously, through various kinds of search in a 2N-dimensional space: (r₁, r₂, . . . , r_{N}, l₁, l₂, . . . , l_{N}).

In accordance with one or more embodiments of the present disclosure, systems and techniques have been described which, given a set of N pairs (resistance, inductance) values at N frequencies f₁, f₂, . . . , f_{N} from a field solver simulation or from a hardware measurement and given DC R and L values, provide a fitting procedure in which one of N resistance relations or N inductance relations are satisfied while minimizing the other of the N resistance relations or the N inductance relations.

According to the example techniques described herein, N resistance relations are always satisfied while minimizing inductance differences. For any inductance fitting result, N given resistance values at N frequencies are exactly matched (e.g., exactly reproduced).

Additionally, or alternatively, according to the techniques described herein, N inductance relations are always satisfied while minimizing resistance differences. For any resistance fitting result, N given inductance values at N frequencies are exactly matched (e.g., exactly reproduced).

According to one or more embodiments of the present disclosure, both approaches (e.g., N resistance relations are always satisfied while minimizing inductance differences, N inductance relations are always satisfied while minimizing resistance difference) may reduce the search domain from a 2N-dimensional space to an N-dimensional space, leading to a reduction in searching time compared to other approaches.

Given a set of pair (resistance, inductance) values (either from measurements or from field solver simulations), the systems and techniques described herein support fitting resistance values exactly or fitting inductance values exactly.

The techniques described herein may be implemented in coplanar waveguide (CPW) models for 28 nm, 22 nm, 14 nm, 10 nm, 7 nm, 5 nm, 3 nm, and 2 nm semiconductor process technology nodes, but are not limited thereto. The techniques described herein may be advantageously applied to EDA evaluation of a backside power distribution network and the clock and signal wires associated with a backside power distribution network. The techniques described herein may be implemented to provide accurate transmission-line models for power grid analysis, accurate SPICE models for global clock-tree design, accurate R-L-C models for co-planar waveguide devices, and accurate SPICE models for passive devices (e.g., inductors). The techniques described herein may provide effective generation of accurate RF models supportive of effective development of RF circuits, microwave devices, and the like. The accurate RF models generated using the techniques described herein, when implemented in design tools, may support effective design analysis of 5G, radar, geosensing, and other microwave circuits.

Aspects of the systems and techniques described herein overcome other approaches for resistance or inductance fitting. Other approaches fail to support fitting multiple resistance values exactly or multiple inductance values exactly as described herein.

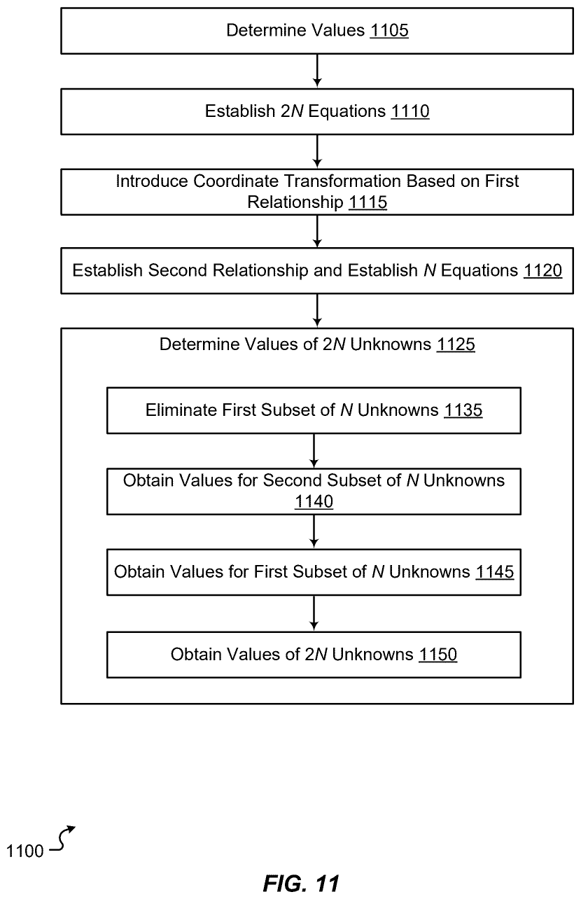

FIG. 11 illustrates an example flowchart of a method 1100 that supports the generation of accurate RF models in accordance with one or more embodiments of the present disclosure. In accordance with one or more embodiments of the present disclosure, the method 1100 is computer-implemented method for modeling a circuit having a resistive element r_{dc}, an inductive element l_{inf}, and element pairs (r₁∥l₁) through (r_{N}∥l_{N}) connected in series, where (rₘ∥lₘ) represents a resistive element rₘ and an inductive element lₘ connected in parallel, and N is a positive integer value.

At 1105, the method 1100 may include determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N}).

In some aspects, determining the value of the inductive element l_{inf} is after determining the values of inductive elements l₁ through l_{N}.

In some aspects, the N frequency values (f₁, f₂, . . . , f_{N}) are equal to or greater than 1 GHz.

In some aspects, determining the values of the resistive elements r₁ through r_{N} and the inductive elements l₁ through l_{N} at the set of N frequency values (f₁, f₂, . . . , f_{N}) includes performing a field solver simulation or on-chip hardware measurements.

In some aspects, determining the value of the resistive element r_{dc} is based on the target DC resistance value; and determining the value of inductive element l_{inf} is based on the target low-frequency inductance value and the N target inductance values.

Non-limiting examples of determining values at 1105 are described with reference to equations (1) through (4).

At 1110, the method 1100 may include establishing a first set of 2N equations including a first set of 2N unknowns (r₁, r₂, . . . , r_{N} and l₁, l₂, . . . , l_{N}) respectively corresponding to the N target resistance values and the N target inductance values.

In an example, the first set of 2N unknowns includes: N resistance values corresponding to the resistive elements included in the element pairs (r₁∥l₁) through (r_{N}∥l_{N}); and N inductance values corresponding to the inductive elements included in the element pairs (r₁∥l₁) through (r_{N}∥l_{N}).

In an example, the first set of 2N equations are associated with solving for the first set of 2N unknowns (r₁, r₂, . . . , r_{N} and l₁, l₂, . . . , l_{N}) in a (2N)-dimensional space.

Non-limiting examples of establishing the first set of 2N equations are described with reference to equation (5) through equation (9d) described herein.

At 1115, the method 1100 may include introducing (or implementing) a coordinate transformation which includes replacing the first set of 2N unknowns with a second set of 2N unknowns in a transformed coordinate system, based on a first relationship.

In an example, the second set of 2N unknowns in the transformed coordinate system includes: N phase values associated with respective pairs of real parts (rₘ) and imaginary parts (2πfₘlₘ) of impedance values (m=1, 2, . . . , N); and N amplitude values associated with the respective pairs of real parts (rₘ) and imaginary parts (2πfₘlₘ) of the impedance values (m=1, 2, . . . , N).

In an example, the second set of N equations are associated with solving for the second subset of N unknowns in the second set of 2N unknowns in an N-dimensional phase space. In some aspects, the N-dimensional phase space is smaller than the (2N)-dimensional space.

Non-limiting examples of introducing (or implementing) the coordinate transformation at 1115 are described with reference to equation (11)

At 1120, the method 1100 may include establishing a second relationship (e.g., equation (15) or equation (18) described herein) expressing a first subset of N unknowns in the second set of 2N unknowns in terms of a second subset of N unknowns in the second set of 2N unknowns, establishing a second set of N equations including the second subset of N unknowns within the second set of 2N unknowns, where the second set of N equations are based on respectively the N target resistance values and the N target inductance values.

In some aspects, determining the second relationship may include using the N resistance equations or using the N inductance equations.

Non-limiting examples of establishing the second set of N equations are described with reference to equations (12) through (16) (or with reference to equations (12) through (14) plus equations (18) and (19)).

At 1125, the method 1100 may include determining the values of the first set of 2N unknowns (r₁, r₂, . . . , r_{N} and l₁, l₂, . . . , l_{N}) based on the first relationship and values of the second set of 2N unknowns.

Non-limiting examples of determining the values of the first set of 2N unknowns are described with reference to equation (11) (after the second set of 2N unknowns are determined).

In some aspects, determining (at 1125) the values of the first set of 2N unknowns (r₁, r₂, . . . , r_{N} and l₁, l₂, . . . , l_{N}) based on the first relationship and values of the second set of 2N unknowns in the transformed coordinate system may include the following, using the second set of N equations.

At 1135, determining the values of the first set of 2N unknowns may include eliminating from the second set of N equations, using the second relationship, the first subset of N unknowns in the N inductance equations or in the N resistance equations.

At 1140, determining the values of the first set of 2N unknowns may include obtaining values for the second subset of N unknowns using the N inductance equations or the N resistance equations.

At 1145, determining the values of the first set of 2N unknowns may include using the second relationship, obtaining values for the first subset of N unknowns.

At 1150, determining the values of the first set of 2N unknowns may include using the first relationship and the values of the second set of 2N unknowns, obtaining the values of the first set of 2N unknowns (r₁, r₂, . . . , l_{N} and l₁, l₂, . . . , l_{N}).

In some aspects, the modeling of the circuit is based on a model of the circuit, where the model includes: a first fit for the N target inductance values at the set of N frequency values; and a second fit for the N target resistance values at the set of N frequency values. In some aspects, the first fit includes an approximate fit, and the second fit is of a higher accuracy compared to the first fit.

In some aspects, the modeling of the circuit is based on a model of the circuit, where the model includes: a first fit for N target resistance values at the set of N frequency values; and a second fit for the N target inductance values at the set of N frequency values. In some aspects, the first fit includes an approximate fit, and the second fit is of a higher accuracy compared to the first fit.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

Various embodiments are described herein with reference to the related drawings. Alternative embodiments can be devised without departing from the scope of the present disclosure. Various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

One or more of the methods described herein can be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

For the sake of brevity, conventional techniques related to making and using aspects of the present disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value, the computer-implemented method comprising:
determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N});
establishing a first set of 2N equations comprising a first set of 2N unknowns (r₁, r₂, . . . , r_{N} and l₁, l₂, . . . , l_{N}) respectively corresponding to the N target resistance values and the N target inductance values;
introducing a coordinate transformation which comprises replacing the first set of 2N unknowns with a second set of 2N unknowns in a transformed coordinate system, based on a first relationship;
establishing a second relationship expressing a first subset of N unknowns in the second set of 2N unknowns in terms of a second subset of N unknowns in the second set of 2N unknowns, and establishing a second set of N equations comprising the second subset of N unknowns within the second set of 2N unknowns, wherein the second set of N equations are based on respectively the N target resistance values and the N target inductance values; and
determining the values of the first set of 2N unknowns (r₁, r₂, . . . , r_{N} and l₁, l₂, . . . , l_{N}) based on the first relationship and values of the second set of 2N unknowns.

2. The computer-implemented method of claim 1, wherein determining the values of the first set of 2N unknowns (r₁, r₂, . . . , r_{N} and l₁, l₂, . . . , l_{N}) based on the first relationship and values of the second set of 2N unknowns in the transformed coordinate system comprises:
using the second set of N equations:
eliminating from the second set of N equations, using the second relationship, the first subset of N unknowns in the N inductance equations or in the N resistance equations;
obtaining values for the second subset of N unknowns using the N inductance equations or the N resistance equations;
using the second relationship, obtaining values for the first subset of N unknowns; and
using the first relationship and the values of the second set of 2N unknowns, obtaining the values of the first set of 2N unknowns (r₁, r₂, . . . , r_{N} and l₁, l₂, . . . , l_{N}).

3. The computer-implemented method of claim 1, wherein determining the value of the inductive element l_{inf} is after determining the values of inductive elements l₁ through l_{N}.

4. The computer-implemented method of claim 1, wherein the modeling of the circuit is based on a model of the circuit, wherein the model comprises:
a first fit for the N target inductance values at the set of N frequency values; and
a second fit for the N target resistance values at the set of N frequency values,
wherein the first fit comprises an approximate fit, and the second fit is of a higher accuracy compared to the first fit.

5. The computer-implemented method of claim 1, wherein the modeling of the circuit is based on a model of the circuit, wherein the model comprises:
a first fit for N target resistance values at the set of N frequency values; and
a second fit for the N target inductance values at the set of N frequency values,
wherein the first fit comprises an approximate fit, and the second fit is of a higher accuracy compared to the first fit.

6. The computer-implemented method of claim 1, wherein the first set of 2N unknowns comprises:
N resistance values corresponding to the resistive elements comprised in the element pairs (r₁∥l₁) through (r_{N}∥l_{N}); and
N inductance values corresponding to the inductive elements comprised in the element pairs (r₁∥l₁) through (r_{N}∥l_{N}).

7. The computer-implemented method of claim 1, wherein the second set of 2N unknowns in the transformed coordinate system comprises:
N phase values associated with respective pairs of real parts (rₘ) and imaginary parts (2πfₘlₘ) of impedance values (m=1, 2, . . . , N); and
N amplitude values associated with the respective pairs of real parts (rₘ) and imaginary parts (2πfₘlₘ) of the impedance values (m=1, 2, . . . , N).

8. The computer-implemented method of claim 1, wherein the first set of 2N equations are associated with solving for the first set of 2N unknowns (r₁, r₂, . . . , l_{N} and l₁, l₂, . . . , l_{N}) in a (2N)-dimensional space.

9. The computer-implemented method of claim 8, wherein:
the second set of N equations are associated with solving for the second subset of N unknowns in the second set of 2N unknowns in an N-dimensional phase space; and
the N-dimensional phase space is smaller than the (2N)-dimensional space.

10. The computer-implemented method of claim 1, wherein the N frequency values (f₁, f₂, . . . , f_{N}) are equal to or greater than 1 GHz.

11. The computer-implemented method of claim 1, wherein determining the values of the resistive elements r₁ through r_{N} and the inductive elements l₁ through l_{N} at the set of N frequency values (f₁, f₂, . . . , f_{N}) comprises performing a field solver simulation or on-chip hardware measurements.

12. The computer-implemented method of claim 1, wherein:
determining the value of the resistive element r_{dc} is based on the target DC resistance value; and
determining the value of inductive element l_{inf} is based on the target low-frequency inductance value and the N target inductance values.

13. The computer-implemented method of claim 1, wherein determining the second relationship comprises using the N resistance equations or using the N inductance equations.

14. A computing system having a memory having computer readable instructions and one or more processors for executing the computer readable instructions, the computer readable instructions controlling the one or more processors to perform operations for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value, the operations comprising:
determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N});
establishing a first set of 2N equations comprising a first set of 2N unknowns (r₁, r₂, . . . , r_{N} and l₁, l₂, . . . , l_{N}) respectively corresponding to the N target resistance values and the N target inductance values;
introducing a coordinate transformation which comprises replacing the first set of 2N unknowns with a second set of 2N unknowns in a transformed coordinate system, based on a first relationship;
establishing a second relationship expressing a first subset of N unknowns in the second set of 2N unknowns in terms of a second subset of N unknowns in the second set of 2N unknowns, and establishing a second set of N equations comprising the second subset of N unknowns within the second set of 2N unknowns, wherein the second set of N equations are based on respectively the N target resistance values and the N target inductance values; and
determining the values of the first set of 2N unknowns (r₁, r₂, . . . , r_{N} and l₁, l₂, . . . , l_{N}) based on the first relationship and values of the second set of 2N unknowns.

15. The computing system of claim 14, wherein determining the values of the first set of 2N unknowns (r₁, r₂, . . . , r_{N} and l₁, l₂, . . . , l_{N}) based on the first relationship and values of the second set of 2N unknowns in the transformed coordinate system comprises:
using the second set of N equations:
eliminating from the second set of N equations, using the second relationship, the first subset of N unknowns in the N inductance equations or in the N resistance equations;
obtaining values for the second subset of N unknowns using the N inductance equations or the N resistance equations;
using the second relationship, obtaining values for the first subset of N unknowns; and
using the first relationship and the values of the second set of 2N unknowns, obtaining the values of the first set of 2N unknowns (r₁, r₂, . . . , r_{N} and l₁, l₂, . . . , l_{N}).

16. The computing system of claim 14, wherein determining the value of the inductive element l_{inf} is after determining the values of inductive elements l₁ through l_{N}.

17. The computing system of claim 14, wherein the modeling of the circuit is based on a model of the circuit, wherein the model comprises:
a first fit for the N target inductance values at the set of N frequency values; and
a second fit for the N target resistance values at the set of N frequency values,
wherein the first fit comprises an approximate fit, and the second fit is of a higher accuracy compared to the first fit.

18. The computing system of claim 14, wherein the modeling of the circuit is based on a model of the circuit, wherein the model comprises:
a first fit for N target resistance values at the set of N frequency values; and
a second fit for the N target inductance values at the set of N frequency values,
wherein the first fit comprises an approximate fit, and the second fit is of a higher accuracy compared to the first fit.

19. The computing system of claim 14, wherein:
the first set of 2N unknowns comprises:
N resistance values corresponding to the resistive elements comprised in the element pairs (r₁∥l₁) through (r_{N}∥l_{N}); and
N inductance values corresponding to the inductive elements comprised in the element pairs (r₁∥l₁) through (r_{N}∥l_{N}); and
the second set of 2N unknowns in the transformed coordinate system comprises:
N phase values associated with respective pairs of real parts (rₘ) and imaginary parts (2πfₘlₘ) of impedance values (m=1, 2, . . . , N); and
N amplitude values associated with the respective pairs of real parts (rₘ) and imaginary parts (2πfₘlₘ) of the impedance values (m=1, 2, . . . , N).

20. A computer program product comprising a computer readable storage medium having program instructions embodied therewith, the program instructions executable by a processor to cause the processor to perform operations for modeling a circuit having a resistive element r_{dc}, an inductive element l_{inf}, and element pairs (r₁∥l₁) through (r_{N}∥l_{N}) connected in series, wherein (rₘ∥lₘ) represents a resistive element rₘ and an inductive element lₘ connected in parallel, and N is a positive integer value, the operations comprising:
determining values of the resistive element r_{dc}, the resistive elements r₁ through r_{N}, the inductive element l_{inf}, and the inductive elements l₁ through l_{N} with respect to a target DC resistance value, a target low-frequency inductance value, and a set of N target resistance values and N target inductance values at a set of N frequency values (f₁, f₂, . . . , f_{N});
establishing a first set of 2N equations comprising a first set of 2N unknowns (r₁, r₂, . . . , r_{N} and l₁, l₂, . . . , l_{N}) respectively corresponding to the N target resistance values and the N target inductance values;
introducing a coordinate transformation which comprises replacing the first set of 2N unknowns with a second set of 2N unknowns in a transformed coordinate system, based on a first relationship;
establishing a second relationship expressing a first subset of N unknowns in the second set of 2N unknowns in terms of a second subset of N unknowns in the second set of 2N unknowns, and establishing a second set of N equations comprising the second subset of N unknowns within the second set of 2N unknowns, wherein the second set of N equations are based on respectively the N target resistance values and the N target inductance values; and
determining the values of the first set of 2N unknowns (r₁, r₂, . . . , r_{N} and l₁, l₂, . . . , l_{N}) based on the first relationship and values of the second set of 2N unknowns.
